(19) United States
(12) Patent Application Publication
(10) Pub. No.: US 2008/0305427 A1
(43) Pub. Date: Dec. 11, 2008

(54) Lithographic Printing Plate

(76) Inventors: Takayuki Sanada, Chiba (JP); Tomoya Terauchi, Nord Rhein-Westfalen (DE); Akihiro Koide, Chiba (JP); Yuko Kobayashi, Tokyo (JP); Hiroko Miyazaki, Chiba (JP)

Correspondence Address: BIRCH STEWART KOLASCH & BIRCH, PO BOX 747, FALLS CHURCH, VA, 22040-0747, US

(21) Appl. No.: 11/658,337

(22) PCT Filed: Oct. 26, 2004
(86) PCT No.: PCT/JP2004/015815

§ 371 Date: Jan. 24, 2007

(51) Int. Cl. G03F 7/00

(52) U.S. Cl. 430/270.1

(57) ABSTRACT

It relates to a processless lithographic printing plate requiring no post treatments after exposure to laser, wherein a difference between the lightness (L*1) of a laser unexposed area and the lightness (L*2) of a laser exposed area after irradiation with laser is 10□(L*2−L*1)<100. An object of the present invention is to provide plate bodies having excellent printing plate inspection in a lithographic printing plate in which drawing with laser light and processless are realized. When the lithographic printing plate of the present invention is used, it is possible to provide a processless lithographic printing plate, which is excellent in sensitivity and resolution, requires no treatments such as development, wiping-off or the like and is excellent in printing plate inspection in the laser exposed area by changing only the surface of the laser exposed area into the oleophilicity.

### TECHNICAL FIELD

The present invention relates to a printing plate, and particularly to a lithographic printing plate that utilizes a fountain solution. Particularly, it relates to a lithographic printing plate, which is sensitive to a light in near infrared region, which can be handled even in a bright room, on which drawing can be directly made with laser light, which does not need operations of development and wiping-off (processless), and which is excellent in various printing properties. Further particularly, it relates to a lithographic printing plate which is excellent in visibility (printing plate inspection) in an exposed area after exposure to laser.

### BACKGROUND ART

With the spread of computers, a so-called Computer To Plate (CTP) type printing plate wherein a copy on the computer is directly printed on a plate body by laser light, thermal head or ink jet to prepare a printing plate without using a process film has been on the market and begun to come into wide use. Of the plates, a printing plate using laser light can be further classified into two types i.e., a photon mode one by light reaction and a heat mode one causing thermal reaction by conducting photothermal conversion. Of these, a CTP plate in a heat mode type has an advantage that it can be handled in a bright room, which is said to be a main stream in the future. Further, the photon mode plates need post processes such as deactivation and development in order that the unexposed area should not react after the exposure. However, the heat mode plates can dispense with such post processes, so it has been expected to obtain a so-called processless plate.

There are various types of processless plates, one of which is a development type on a printing press. For example, this type is to remove an area having low adhesion properties on the printing press by laminating both of a oleophilic layer and an ink-repellent layer or both of a oleophilic layer and a hydrophilic layer on a support body for changing the adhesion properties between a layer on the upper side and a lower layer thereof by exposure to laser. To remove an area having low adhesion properties, various methods such as contact with a water-supply roller, contact with an ink roller, peeling due to tackiness of ink, contact with a blanket cylinder and the like have been used. In a printing plate of the development type on the printing press, as at least a part of a surface layer removed from the printing press, in order to prevent coloring contamination of a fountain solution and ink of the printing press, a layer to be removed is preferably desired not to be colored, and thus it is difficult to give an excellent printing inspection.

In order to solve such problems, for example, a printing plate in which a printing inspection is given by preparing a heat sensitive layer containing an infrared rays absorbing pigment for changing the optical density due to the exposure is disclosed in JP1999-240270A and JP2004-167904A. However, such an infrared rays absorbing pigment is generally faded away due to exposure to infrared rays, but never completely decolored so that contrast between a laser exposed area and an unexposed area is low and a printing plate inspection can not be said to be enough. Further, even when the exposed area on the surface layer was removed, this plate had a problem that a small amount of a coloring material was blended with the fountain solution and ink of the printing press for causing coloring contamination. On the other hand, when the unexposed area on the surface layer was removed, as coloring density became higher, a printing plate inspection was improved, but coloring contamination on the printing press became severe, both of which could not be achieved at the same time.

As another method, for example, a printing plate in which a printing plate inspection is given by preparing a photosensitive layer containing a developer and a heat sensitive pigment that is color-developed by the heat is disclosed in JP2004-50616A and JP2004-122363A. When the unexposed area on the surface layer is removed, the unexposed area is not color-developed, being colorless or pale-colored, thus causing no problem in coloring contamination on the printing press. However, such a heat sensitive pigment generally has a hydrophilic group such as a carboxyl group or the like in a color-developing structure, there is a problem that it is dissolved in a fountain solution on the printing press to cause a coloring contamination. Further, there is a possibility to exert a bad influence on the printing performance such as deterioration of hydrophilicity and deterioration of printing durability by the heat sensitive pigment and developer used only to obtain a printing inspection, thus such a technology is hardly put into practical use.

As other types of processless plates, a polarity conversion type can be mentioned. This type employs, for example, a structure for converting only the exposed area of the hydrophilic resin photosensitive layer from the hydrophilicity to the oleophilicity by exposure to laser on the support body. As the surface of the plate after the exposure is already divided into the hydrophilicity and the oleophilicity, a removal process on the printing press is not necessary and a complete processless plate can be made. As a type of this printing plate, for example, a printing plate wherein a photosensitive layer in which oleophilic polymer particles are dispersed in the hydrophilic polymer matrices is converted to ink-receptive as the hydrophilicity is lost by foaming a oleophilic polymer or doing heat fusion due to exposure to laser is disclosed in WO2001/83234A. The surface of the photosensitive layer becomes opaque by the exposure, whereby this plate enables a printing plate inspection, but contrast is small and improvement of a printing plate inspection has been desired.

[Patent Document 1] JP1999-240270A

[Patent Document 2] JP2004-167904A

[Patent Document 3] JP2004-50616A

[Patent Document 4] JP2004-122363A

[Patent Document 5] WO2001/83234A

### DISCLOSURE OF THE INVENTION

An object of the present invention is to provide plate bodies having excellent printing plate inspection in a lithographic printing plate in which drawing with laser light and processless are realized.

In a lithographic printing plate in which drawing with laser light and processless are realized, the applicant has paid attention to a phenomenon in which a laser exposed area became opaque and found that sufficient contrast between the opaque exposed area and dark unexposed area can be obtained by making the lightness of a laser unexposed area in a particular range. That is, the present invention is configured as follows:

(1) a processless lithographic printing plate requiring no post treatments after exposure to laser, wherein a difference between the lightness (L*1) of a laser unexposed area and the lightness (L*2) of a laser exposed area after irradiation with laser is 10≦(L*2−L*1)<100; preferably,

(2) the processless lithographic printing plate according to claim 1, wherein the lightness (L*1) of a laser unexposed area is not less than 0 and not more than 20; further preferably,

(3) the processless lithographic printing plate according to claim 1, wherein a photosensitive layer is formed on a support body with an under layer interposed therebetween and a pigment in order to have the lightness (L*1) of a laser unexposed area of not less than 0 and more than 20 is contained in the under layer; further preferably,

(4) the processless lithographic printing plate according to claim 1, wherein a photosensitive layer is formed directly on a support body or with an under layer interposed therebetween and a pigment in order to have the lightness (L*1) of a laser unexposed area of not less than 0 and not more than 20 is contained in the support body; further preferably,

(5) the processless lithographic printing plate according to claim 1, wherein a photosensitive layer is formed directly on a support body or with an under layer interposed therebetween, the support body is transparent, the support body has a layer on the back surface thereof in which a pigment in order to have the lightness (L*1) of a laser unexposed area of not less than 0 and not more than 20 is contained; and

(6) a processless lithographic printing original plate requiring no post treatments after exposure to laser, wherein a difference between the lightness (L*1) of a laser unexposed area and the lightness (L*2) of a laser exposed area after irradiation with laser is 10≦(L*2−L*1)<100.

### BEST MODES FOR CARRYING OUT THE INVENTION

The lithographic printing plate according to the present invention will be explained in detail below.

[Lightness Difference]

The lightness in the present invention is a value according to an L*a*b* color system regulated in JIS Z 8729. That is, in the L*a*b* color system, L* refers to the lightness, a*b* refers to chromaticity indicating the hue and chroma. In the present invention, the lightness of the laser unexposed area is expressed as L*1 while that of the exposed area is expressed as L*2. At this time, a difference between the lightness of the laser unexposed area and that of the exposed area is represented by the following formula.

Lightness Difference: L*2−L*1

In the plate according to the present invention, the lightness becomes more important than chroma in view of the fact that the laser exposed area becomes opaque. Therefore, in order to accomplish an excellent printing plate inspection, it is required that the lightness difference (L*2−L*1) between the laser unexposed area and the exposed area is not less than 10. If the lightness difference is not less than 10, light and darkness of the laser exposed area and unexposed area becomes obvious, thus improving a printing plate inspection. More preferably, the lightness is not less than 15. If the lightness difference is less than 10, it is difficult to distinguish between the opaque laser exposed area and the laser unexposed area, thus making it difficult to inspect printing plates. Further, the possible range of the lightness (L*2−L*1) is less than 100.

The lightness L* can be measured by using a commercial densitometer or a calorimeter, which can be measured, for example, by using a spectro-colorimeter CM-2002 manufactured by Konica Minolta, a spectro-color-densitometer x-rite528JP manufactured by X-Rite, a spectro-densitometer Spectropens Advance manufactured by Techkon GmbH, and a spectrophotometer Spectro Eye manufactured by GretagMacbeth AG.

[Darkening of Laser Unexposed Area]

In the present invention, it is preferable to have an excellent printing plate inspection by having the lightness L*1 of the laser unexposed area in the range of not less than 0 and not more than 20. The lightness L*1 of not less than 0 and not more than 20 means coloring of the printing original plate with dark color or black color in order for strong absorption over the wide range of the visible area. Here, as a method of adding a pigment in order to have the lightness L*1 of the laser unexposed area in the range of not less than 0 and not more than 20, there can be exemplified, for example, a method of forming a photosensitive layer on a support body with an under layer interposed therebetween for adding a pigment in order to have the lightness L*1 of an unexposed area in the range of not less than 0 and not more than 20 to the under layer, a method of arranging a pigment in order to have the lightness L*1 of an unexposed area in the range of not less than 0 and not more than 20 contained in a support body, a method of having a support body being transparent and having a layer comprising a pigment in order to have the lightness L*1 of an unexposed area in the range of not less than 0 and not more than 20 in the back side of the support body and the like. Concrete embodiments of the respective methods are described later.

[Pigment to be Added]

In the present invention, in order to have the lightness L*1 of the laser unexposed area in the range of not less than 0 and not more than 20, it is preferable to add a pigment in order to have the lightness L*1 of the unexposed area of the plate in the range of not less than 0 and not more than 20 to the back side layer of the transparent support body, under layer or support body. Such a pigment to be added to the back side layer of the transparent support body, under layer or support body is preferably dark pigment as such, that is, ranging from dark color to black color. Or even if a pigment is not dark color as such, when a light absorbing agent (pigment) for absorbing laser light added to the photosensitive layer is contained, a pigment in order to have the lightness L* of the laser unexposed area in the range of not less than 0 and not more than 20 in combination with the light absorbing agent (pigment) is also preferable. In this case, a pigment having the absorption max (λ max) in a wavelength region that is different from the light absorbing agent to be added to the photosensitive layer can be selected. λ max of the pigment to be added to the back side layer of the transparent support body, under layer or support body is not less than 100 nm, preferably not less than 150 nm distant from λ max of the light absorbing agent. In other words, the color of the pigment itself is preferably carbon black or Sudan black B close to black, and crystal violet including dark purple such as purple or the like even if it is not black. In particular, in order to make the unexposed area dark color regardless of the color of the pigment to be added to the photosensitive layer, a pigment having the color of the pigment itself close to black is desirable.

Concrete examples of the pigment in order to have the lightness L*1 of the laser unexposed area in the range of not less than 0 and not more than 20 include cyanine compounds, polymethine compounds, phthalocyanine compounds, anthracyanine compounds, porphyrin compounds, azo compounds, benzoquinone compounds, naphthoquinone compounds, squalelium pigments, pyrylium pigments, triarylmethane compounds, anthraquinone compounds, indigo compounds, dithiol metal complexes, metal complexes of diamine and the like, in addition to black pigments such as carbon black, black iron oxides, aniline black, perylene black, trisazo pigments, leuco pigments and the like, purple pigments such as crystal violet and the like. Carbon black and crystal violet are preferable. These may be used either singly or in a mixture of two or more.

When these pigments in order to have the lightness L*1 of the unexposed area in the range of not less than 0 and not more than 20 are added to the under layer, these pigments may be dissolved or dispersed in a resin used for the under layer. For the formation of the under layer, a support body is coated with a solution or dispersion for the under layer, and then the solution or dispersion is dried and further heated as required. As a method of coating the solution or dispersion for the under layer, there can be exemplified, for example, a bar coating method, a roll coater method, a blade coater method, a gravure coater method, a curtain flow coater method, a die coater method, a dip coater method, a spraying method and the like. The amount of the pigment used may be good as far as the lightness of the unexposed area is selected within the aforementioned range. Then, it is not particularly restricted. However, it is preferably from 0.1 to 300 weight parts and more preferably from 0.5 to 100 weight parts based on 100 weight parts of the resin. The amount within the aforementioned range is preferable because it is easy to make the dark color, the under layer is strong, and it is difficult to cause trouble with peeling during printing accordingly. Further, at this time, various additives such as a dispersing agent, a wetting agent and the like may be used as well. Examples of various additives include nonionic surfactants, anionic surfactants, water-soluble resin and the like.

In the present invention, when a pigment in order to have the lightness L*1 of the laser unexposed area in the range of not less than 0 and not more than 20 is added to the support body, there can be exemplified, for example, a method of adding a pigment during the polymerization reaction of the resin such as polyester, polyethylene, polypropylene or after completion of the polymerization reaction and the like for preparing a pigment-containing master pellet and making this pigment-containing master pellet into a film, a method of adding a pigment in the aforementioned resin for melt-kneading and making films or the like. In this manner, pigment-containing films have already been on the market. As for such films containing a black pigment such as carbon black or the like, there can be mentioned, for example, LUMIRROR (registered trademark) X30 manufactured by Toray Industries, Inc., MELINEX (registered trademark) 427 manufactured by Teijin DuPont Films Japan Ltd., DIALAMY (registered trademark) manufactured by Mitsubishi Plastics, Inc. and the like. These products can also be used. The amount of the pigment used may be good as far as the lightness of the unexposed area of the plate is adjusted to be within the aforementioned range. Then, it is not particularly restricted. However, it is preferably from 0.1 to 100 weight parts and more preferably from 1 to 50 weight parts based on 100 weight parts of the resin. The amount within the aforementioned range is preferable because it is possible to make the dark color, it is easy to make films, prepared films becomes brittle and are not ruptured during printing, and the like.

Further, another preferred embodiment of the present invention is a multi-layered support body in which a film containing a pigment in order to have the lightness L*1 of the laser unexposed area in the range of not less than 0 and not more than 20 is attached to the other support body as well. The methods of attaching to the other support body include a method of using an adhesive and a laminate method.

Further, in case of a transparent film, another preferred embodiment of the present invention is to coat the back side with a solution or dispersion containing a pigment in order to have the lightness L*1 of the unexposed area in the range of not less than 0 and not more than 20 or to attach a film containing a pigment in order to have the lightness L*1 of the unexposed area in the range of not less than 0 and not more than 20 to the back side. As a method of coating the back side with a solution or dispersion containing a pigment in order to have the lightness of the unexposed area in the range of not less than 0 and not more than 20, there can be exemplified, for example, a method of coating the back side of the transparent film with a solution for the back side layer in which the pigment is dissolved and dispersed in the resin and then drying the solution or dispersion and further heating as required, and the like. As a method of coating of the solution or dispersion for the back side layer, there can be exemplified, for example, a bar coating method, a roll coater method, a blade coater method, a gravure coater method, a curtain flow coater method, a die coater method, a dip coater method, a spraying method and the like. The amount of the pigment used is not particularly restricted as far as the lightness of the unexposed area is adjusted to be within the aforementioned range. However, it is preferably from 0.1 to 300 weight parts and more preferably from 0.5 to 100 weight parts based on 100 weight parts of the resin. The amount within the aforementioned range is preferable in the view of the facts that it is easy to make the dark color; the back side layer is strong as the amount of resin is sufficient, thus the pigment is not eliminated due to rubbing and the like. Further, at this time, various additives such as a dispersing agent, a wetting agent and the like may be used as well. Examples of various additives include nonionic surfactants, anionic surfactants, water-soluble resin and the like. As a method of attaching a film containing a pigment in order to have the lightness L*1 of the unexposed area in the range of not less than 0 and not more than 20 to the back side, there can be exemplified, for example, a method of attaching the black pigment-containing film that has already been commercialized to the back side of the transparent film. Examples of methods of attaching include a method of employing an additive and a laminate method. Here, the transparent film refers to a film in which the light transmittance in the visible light of from 380 to 780 nm is not less than 50% and preferably not less than 80%. When the light transmittance is not more than 50%, the effect of the back side layer becomes small. In this case, it is preferable to employ a method of adding to the aforementioned under layer.

[Support Body]

In the lithographic printing plate of the present invention, a photosensitive layer having an ink-repellent (hydrophilic) is preferably prepared directly on the support body or with the other layer interposed therebetween. The kind of a support body used here is not particularly restricted. Concrete examples of the support body include metallic plates such as aluminum plate, steel plate, stainless steel plate, copper plate and the like, alloyed plates of these metals, plastic films such as films of polyester, polyamide (nylon), polyethylene, polypropylene, polycarbonate, ABS resin, cellulose acetate and the like, laminated films such as paper, aluminum foil laminated paper, metal deposited paper, plastic laminated paper and the like. Aluminum plates are particularly preferable as they are easy to handle, hardly get rusty, are less extensible, suitable for long-time printing and inexpensive. In the plastic films, polyester is particularly preferable as it is excellent in physical properties such as heat resistance and the like, and mechanical properties such as tensile strength and the like, and it is inexpensive. The thickness of the support body is not particularly restricted. However, the thickness is usually about from 100 to 500 μm. Further, in order to improve the adhesion properties, these support bodies may be subjected to surface treatments such as oxidation treatment, chromate treatment, zinc phosphate treatment, sandblasting treatment, corona discharge treatment and the like. And, a method of forming a photosensitive layer on the support body with the other layer interposed therebetween is effective as well.

Here, when a support body containing a pigment in order to have the lightness L*1 of the unexposed area in the range not less than 0 and not more than 20 of the present invention is used, it is preferable to use a transparent support body such as polyester, polyethylene, polypropylene and the like. Further, when a pigment in order to have the lightness L*1 of the aforementioned unexposed area in the range of not less than 0 and not more than 20 is contained in the back side layer, the same as mentioned before.

[Photosensitive Layer]

In the lithographic printing plate of the present invention, a photosensitive layer is preferably formed directly on the support body or with the other layer interposed therebetween and it is more preferably a hydrophilic photosensitive layer having the hydrophilicity. The hydrophilic photosensitive layer is preferably forming a oleophilic image area on the surface of the photosensitive layer by fusion and foaming due to the exposure. Further, the photosensitive layer in the present invention is preferable such that its surface is ink-repellent (hydrophilic) at a laser unexposed state and it is changed from ink-repellent to oleophilic by exposure to laser. In particular, by applying to offset printing utilizing a fountain solution, as the laser unexposed area is hydrophilic, being covered with a fountain solution, thus having ink-repellent properties, i.e., repelling ink. Here, the photosensitive layer needs to be undissolved by contact with a fountain solution. For this reason, it is preferable to crosslink a hydrophilic polymer for water resistance.

As the photosensitive composition for forming such a photosensitive layer, there can be exemplified, for example, a photosensitive composition containing a hydrophilic polymer, a crosslinking agent and a light absorbing agent or a photosensitive composition containing a hydrophilic polymer, a crosslinking agent, a oleophilic polymer or a light absorbing agent, and the like. In the present invention, a photosensitive layer is more preferably formed by crosslinking after coating the support body using the latter photosensitive composition containing the oleophilic polymer. The film thickness of the photosensitive layer is not particularly restricted. However, the thickness after thermal treatment is usually desired to be about 0.5 to 20 μm and particularly 1 to 10 μm.

[Hydrophilic Polymer]

In the present invention, the hydrophilic polymer used for the photosensitive composition for forming a photosensitive layer is preferably a polymer having a functional group capable of reacting with a hydrophilic group and a crosslinking agent on the side chain.

As the hydrophilic group, there can be exemplified, for example, hydroxyl group, carboxyl group and its alkali metal salts, alkali earth metal salts or amine salts, sulfonate group and its alkali metal salts, alkali earth metal salts or amine salts, phosphate group and its alkali metal salts, alkali earth metal salts or amine salts, amide group, amine group, sulfonamide group, oxymethylene group, oxyethylene group and the like.

Also, as the functional group capable of reacting with a crosslinking agent, there can be exemplified, for example, isocyanate group, glycidyl group, oxazolyl group, methylol group, and methoxymethyl group and butoxymethyl group, which are obtainable by condensing methylol group with an alcohol such as methanol, butanol or the like, in addition to the aforementioned hydrophilic groups.

As the polymer having the hydroxyl group on the side chain, there can be exemplified, for example, a polyvinyl alcohol polymer, a homopolymer and a copolymer which can be obtained by polymerizing unsaturated monomers having a hydroxyl group and various modified polymers of these polymers. The polyvinyl alcohol polymer is described in more detail. Examples of the polyvinyl alcohol polymer include a polymer which can be obtained by hydrolysis in part or in whole of a homopolymer or a copolymer of fatty acid vinyl monomer such as vinyl acetate, vinyl propionate and the like, its partially formalized polymer, partially acetalized polymer, partially butyralized polymer and the like. Further, as the unsaturated monomer having a hydroxyl group, there can be exemplified, for example, hydroxyethyl (meth)acrylate, hydroxypropyl (meth)acrylate, hydroxybutyl (meth)acrylate, monomers obtained by addition of ethylene oxide or propylene oxide to these (meth)acrylates, and methylol (meth)acrylamide or methoxymethyl (meth)acrylamide or butoxymethyl (meth)acrylamide that are condensation products of the methylol (meth)acrylamide and methyl alcohol or methylol (meth)acrylamide and butyl alcohol, and the like.

As the polymer having a carboxyl group on the side chain, there can be exemplified, for example, a homopolymer or a copolymer which can be obtained by polymerizing unsaturated monomers containing a carboxyl group such as dibasic unsaturated acids (i.e. (meth)acrylic acid, itaconic acid, fumaric acid, maleic acid and anhydrides thereof and the like) and monoesters and monoamides of these dibasic unsaturated acids, and various modified polymers of these polymers.

As the polymer having a sulfonate group on the side chain, there can be exemplified, for example, a homopolymer or a copolymer which can be obtained by polymerizing vinyl sulfonate, sulfoethyl (meth)acrylate, (meth)acrylamide methylpropane sulfonic acid, vinylmethyl sulfonic acid, isoprophenylmethyl sulfonic acid, sulfonic acid esters of an alcohol obtained by addition of ethylene oxide or propylene oxide to (meth) acrylic acid (e.g., product name: ELEMINOL RS-30, manufactured by Sanyo Chemical Industries, Ltd.), (meth) acryloyloxyethylsulfonic acid, esters of a monoalkylsulfosuccinate and a compound having an allyl group (e.g., product name: ELEMINOL JS2, manufactured by Sanyo Chemical Industries, Ltd.; product names: LATEMUL S-180 or LATEMUL S180A, manufactured by Kao Corporation), reaction products of monoalkylsulfosuccinates and glycidyl (meth)acrylate, product name: Antox MS60 manufactured by Nippon Nyukazai Co., Ltd. and the like, and various modified polymers of these polymers. In the polymer having these sulfonate groups, the sulfonate group may be neutralized with inorganic bases such as sodium hydroxide, potassium hydroxide and the like or amines.

As the polymer having a phosphate group on the side chain, there can be exemplified, for example, a homopolymer and a copolymer which can be obtained by polymerizing vinylphosphate, mono(2-hydroxyethyl)phosphate (meth)acrylate, mono(2-hydroxyethyl)(meth)acrylate of a monoalkyl phosphate and the like, and various modified polymers of these polymers.

The polymers having the carboxyl group, sulfonate group and phosphate group may be neutralized with inorganic bases or amines for forming alkali metal salts, alkali earth metal salts or amine salts. Examples of the alkali metal include sodium, potassium, lithium and the like. Examples of the alkali earth metal include calcium, magnesium and the like. Examples of the amines include ammonia, methylamine, dimethylamine, trimethylamine, ethylamine, diethylamine, triethylamine, monoethanolamine, diethanolamine, triethanolamine and the like.

As for the polymer having an amide group on the side chain, there can be exemplified, for example, a homopolymer and a copolymer which can be obtained by polymerizing unsaturated monomers having unsubstituted or substituted amide groups, and various modified polymers of these polymers (e.g., polymers obtained by addition of hydrolysis polymer, various compounds and the like). As for the unsaturated monomer having unsubstitued or substituted amide groups, there can be exemplified, for example, unsubstituted or substituted (meth)acrylamides, amidated monomer of dibasic acids such as itaconic acid, fumaric acid, maleic acid and the like, N-vinylacetamide, N-vinylformamide, N-vinylpyrrolidone and the like. More concrete examples of the unsubstituted or substituted (meth)acrylamides include (meth)acrylamide, N-methyl (meth)acrylamide, N,N-dimethyl (meth)acrylamide, N-ethyl (meth)acrylamide, N,N-diethyl (meth)acrylamide, N,N-dimethylaminopropyl (meth)acrylamide, N-isopropyl (meth)acrylamide, diacetone (meth)acrylamide, methylol (meth)acrylamide, methyoxymethyl (meth)acrylamide, butoxymethyl (meth)acrylamide, propyl sulfonate (meth)acrylamide, (meth)acryloyl morpholine and the like. Further, the amidated monomer of dibasic acids such as itaconic acid and the like may be monoamide in which a carboxyl group in one side is amidated, diamide in which carboxyl groups in both side are amidated or amide ester in which a carboxyl group in one side is amidated and a carboxyl group in the other side is esterified. Incidentally, in the present invention, the terms described as in the aforementioned “(meth)acryl, (meth)acrylate, (meth)acryloyl” and the like refer to both of acryl and methacryl, both of acrylate and methacrylate, and both of acryloyl and methacryloyl respectively.

In the present invention, as for the hydrophilic polymer for use in the photosensitive composition for forming the photosensitive layer, a homopolymer and a copolymer which can be obtained by polymerizing unsaturated monomers having amide groups such as (meth)acrylamide, N-methyl (meth)acrylamide, N,N-dimethyl (meth)acrylamide, N-ethyl (meth)acrylamide, N,N-diethyl (meth)acrylamide, N-isopropyl (meth)acrylamide, methylol (meth)acrylamide, N-vinylacetamide, N-vinylformamide, N-vinylpyrrolidone and the like are particularly preferable as they can achieve both high hydrophilicity and high water resistance by crosslinking.

Furthermore, in the hydrophilic polymer which can be used for the present invention, in order to further improve the effect of the present invention, other copolymerizable unsaturated monomers can also be copolymerized, in addition to unsaturated monomers having the hydrophilic substituent group and unsaturated monomers having a crosslinkable functional group. As for the copolymerizable unsaturated monomer, there can be exemplified, for example, methyl (meth)acrylate, ethyl (meth)acrylate, butyl (meth)acrylate, 2-ethylhexyl (meth)acrylate, glycidyl (meth)acrylate, dimethylaminoethyl (meth)acrylate, diethylaminoethyl (meth)acrylate, phenoxyethyl (meth)acrylate, benzyl (meth)acrylate, isoboronyl (meth)acrylate, adamanthyl (meth)acrylate, cyclohexyl (meth)acrylate, styrene, α-methylstyrene, acrylonitrile, methacrylonitrile, vinyl acetate and the like.

[Crosslinking Agent]

In the present invention, the crosslinking agent for use in the photosensitive composition for forming the photosensitive layer is not particularly restricted as far as the crosslinking agent may undergo crosslinking reaction with the hydrophilic polymer to make the hydrophilic polymer water-insoluble, thereby improving water resistance of the photosensitive layer. Examples of the crosslinking agent include publicly known polyhydric alcohol compounds, polycarboxylic acid compounds and anhydrides thereof, polyglycidyl compounds (epoxy resins), polyamine compounds, polyamide compounds, polyisocyanate compounds (including block isocyanates), oxazoline resins, amino resins, glyoxal and the like that react with the crosslinkable functional group (e.g., carboxyl group, sulfonate group, hydroxyl group, or glycidyl group, or in some cases, an amide group) in the hydrophilic polymer. According to the present invention, among the aforementioned crosslinking agents, a curing agent for epoxy resins such as publicly known various polyglycidyl compounds (epoxy resins), oxazoline resins, amino resins, polyamine resins, polyamide resins or the like, and glyoxal are preferably used from the viewpoints of the curing rate, the stability of the photosensitive composition, and the balance between hydrophilicity and water resistance of the photosensitive layer. Examples of the amino resin include publicly known melamine resins, urea resins, benzoguanamine resins, glycoluril resins, and modified resins of these resins such as carboxy-modified melamine resins and the like. Further, in order to promote the crosslinking reaction, in the use of the aforementioned glycidyl compound, tertiary amines may be used in combination, and in the use of the amino resin, acidic compounds such as p-toluenesulfonic acid, dodecylbenzene sulfonic acid, ammonium chlorides or the like may be used in combination.

[Light Absorbing Agent]

In the present invention, the light absorbing agent which can be contained in the photosensitive composition may be one which absorbs a light to generate heat. The wavelength of the light to be absorbed is not particularly restricted. In the exposure, a light of a wavelength region to be absorbed by the light absorbing agent is appropriately used. Concrete examples of the light absorbing agent include cyanine pigments, polymethine pigments, phthalocyanine pigments, naphthalocyanine pigments, anthracyanine pigments, porphyrin pigments, azo pigments, benzoquinone pigments, naphthoquinone pigments, dithiol metal complexes, diamine metal complexes, nigrosine and the like.

In these light absorbing agents, it is preferable to use a light absorbing agent which has the absorption region at from 700 to 1200 nm from the viewpoints of handling in a bright room, power of a light source used for the exposure, and ease of use, particularly at from 800 to 860 nm that is the oscillation wavelength of commercialized high-power semiconductor laser and which is excellent in sensitivity and resolution characteristic from the viewpoints of. The absorption wavelength region of these agents can be adjusted by a substituent, the length of the conjugated system of a n electron or the like. These light absorbing agents may be dissolved or dispersed in the photosensitive composition.

[Oleophilic Polymer]

The oleophilic polymer for use in the photosensitive composition of the present invention is preferably an emulsified type in which polymer particles are dispersed in water, and may be a self emulsified type or a forcibly emulsified type. This can be prepared by emulsion polymerization, suspension polymerization, graft polymerization, post emulsion of polymer and the like. As for the oleophilic polymer, there can be exemplified, for example, urethanes, (meth)acryl resin emulsion, styrene, vinyl acetate, vinylidene chloride, conjugated diene rubbers, butadiene rubbers and the like. The oleophilic polymer used for these may be used not only singly but in combination of two or more kinds. When these are added, the hydrophilic photosensitive layer takes a phase separation structure of crosslinked hydrophilic polymer phase and a oleophilic polymer phase thereof. At this time, from the viewpoint of prevention of scumming in a non-image area, the oleophilic polymer phase is preferably dispersed in the crosslinked hydrophilic polymer phase. The average particle diameter of the polymer particle used as the oleophilic polymer is preferably from 0.005 to 0.5 μm and more preferably not more than 0.1 μm.

[Other Additives]

In the present invention, a hydrophilic additive may be further added to the photosensitive composition. The hydrophilic additive is desired to be dissolved in water or an organic solvent. Any compounds can be used as far as the hydrophilicity on the surface of the printing plate is improved by the hydrophilic additive for acting such that a fountain solution is attached to the surface immediately after printing is started. Particularly, compounds called surfactants or surface modifiers are preferable. For example, a hydrophilic surfactant described in [Special Function Sufactants] published by CMC Publishing Co., Ltd. (1986) can be used. Concrete examples are described below.

As for the nonionic surfactant, there can be exemplified, for example, polyethylene glycol types such as polyoxyethylene alkyl ether, polyoxyethylene polypropylene glycol ether, polyoxyethylene alkyl phenyl ether, polyoxyethylene fatty acid ester, polyoxyethylene sorbitan fatty acid ester, polyoxyethylene sorbitol fatty acid ester, polyoxyethylene alkyl amine and the like, polyhydric alcohol types such as alkylalkanolamide, glycerin fatty acid ester, sucrose fatty acid ester, sorbitan fatty acid ester, surfactant having a raw material of coconut oil or castor oil, polyethylene glycol, alkylphenyl ether or alkyl ether, alkyl aryl ether, lauryl ether surfactants and the like.

As for the cationic surfactant, there can be exemplified, for example, primary amine salt, secondary amine salt, tertiary amine salt, quaternary ammonium salt, quaternary pyridinium salt, lauryl imidazolin salt, alkyl amine and the like.

As for an amphoteric surfactant, biionic surfactants such as alkylbetaine, amino acid type, sulfonic acid type, sulfonic acid ester type, phosphate ester type, amine oxide type, polyoxyethylene alkylamine type, polyalkylene polyamine type, polyethylene imine type, carboxylic acid type, sulfonic acid ester type and the like can be used.

As for the anionic surfactant, there can be exemplified, for example, sulfonic acid salts such as sodium alkylphenyl sulfonate, sodium alkylnaphthalene sulfonate, sodium alkylaryl sulfonate, sodium naphthalene sulfonate, sodium salts of formalic condensation products of naphthalene sulfonate, sodium polyoxyethylene alkylsulfosuccinate, sodium dialkylsulfosuccinate and the like. Further, carboxylic acid salts such as sodium dialkyl succinate, sodium monoalkyl succinate, polycarboxylic acid and the like can be cited. Sulfate ester salts such as alkyldiphenyl sulfate oxide, alkyl sulfonate, sodium higher alcohol sulfate, sodium polyoxyethylene alkylsuffonate ether or ammonium and the like can be exemplified. Further, phosphoric acid ester salts such as sodium alkylether phosphate or sodium alcohol phosphate and the like can be used. In particular, sulfonic acid salts such as sodium dialkylsulfosuccinate or sodium monoalkyl sulfosuccinate and the like or phosphate salts such as sodium alkylether phosphate, sodium alcohol phosphate and the like are particularly preferable as it is difficult to leach even though the surface of the photosensitive layer gets wet.

As for fluorine sufactants, there can be exemplified, for example, perfluoro alkylsulfonic acid salt, perfluoro alkylcarboxylic acid salt, perfluoro alkylphosphoric acid ester, perfluoro alkylammonium salt, perfluoro alkylbetaine, perfluoro alkylamine oxide, perfluoro alkylethylene oxide adduct, hexafluoro propene oligomer carboxylic acid salt, hexafluoro propene oligomer sulfonic acid salt, hexafluoro propene oligomer phosphonic acid, hexafluoro propene oligomer betaine, hexafluoro propene oligomer ammonium salt and the like. These additives may be used in combination of two or more kinds at the same time.

[Compounding Ratio of Photosensitive Composition]

In the photosensitive composition of the present invention, the ratio of the hydrophilic polymer, oleophilic polymer, crosslinking agent, light absorbing agent used is not particularly restricted as far as it is reviewed from the viewpoints of the balance between the hydrophilicity and the water resistance of the photosensitive layer of the printing plate, sensitivity to the laser exposure, other various printing characteristics, and economy. However, the amount of the hydrophilic polymer as a solid content is preferably from 87 to 10 weight parts, the amount of the oleophilic polymer is preferably from 80 to 10 weight parts, and the amount of the crosslinking agent is preferably from 3 to 50 weight parts. When these are weight parts in total, the amount of the light absorbing agent is preferably 2 to 30 weight parts, based on the total 100 weight parts of the solid content of the hydrophilic polymer, oleophilic polymer and crosslinking agent. More preferably, the hydrophilic polymer is from 60 to 20 weight parts, the oleophilic polymer is from 70 to 20 weight parts, the crosslinking agent is from 5 to 40 weight parts, and the light absorbing agent is from 3 to 20 weight parts, based on the total 100 weight parts of the solid content of the hydrophilic polymer, oleophilic polymer and crosslinking agent.

[Under Layer]

According to the present invention, an under layer may be provided between the support body and the photosensitive layer. From the viewpoint of the adhesion properties, the same resin as the oloephilic polymer contained in the photosensitive composition is desired to be used for the under layer used at this time. The resin is desired to be particularly a oleophilic polymer of urethane resin, acryl resin, vinyl acetate resin, synthetic rubber resin and ethylene resin. When the same kind as the oleophilic polymer used for the photosensitive composition is used for the oleophilic polymer forming the under layer, general physical properties, for example the molecular weight do not need to be the same. The resin used for making the under layer may be the uniform solution which is dissolved in an aqueous solution or an organic solvent or may be emulsified. Particularly preferable is a polymer emulsion type. The oleophilic polymer emulsion may be a forcibly emulsified type or a self emulsified type.

The average particle diameter of the emulsion is generally measured by a particle size analyzer (for example, [Microtrac] and the like) after diluting with water. Besides, the emulsion can be measured by a transmission electron microscope by slicing it after freezing, which can be preferably used particularly when the average particle diameter is not more than 10 nm. The emulsion needs a film-forming characteristic by fusion after coating if the dispersion solvent is evaporated. If there is no problem in the production, any film-making temperature may be good.

The under layer may be used in combination of 1 or 2 or more of the oleophilic polymer resins. Furthermore, a strong film can be produced by adding a crosslinking agent. To coat the under layer, a bar coating method, a roll coater method, a blade coater method, a gravure coater method, a curtain flow coater method, a die coater method, a dip coater method, a spraying method and the like may be used. At this time, in order to remove foam in the coating solution, to improve the adhesion properties to the support body by smoothing the coating film, and to improve the adhesion properties to the hydrophilic photosensitive layer, various additives such as an anti-foaming agent, a leveling agent, a repelling inhibitor, a coupling agent and the like may also be used. The film thickness of the under layer is not particularly restricted. However, usually it is approximately from 0.1 to 20 μm and preferably from 0.2 to 10 μm.

The photosensitive composition may be coated as such after coating the under layer, may be heated or dried by ventilating air. As the adhesion properties between the support body and the photosensitive layer are increased due to the thus-prepared under layer, printing durability is good, and no peeling takes place on the surface even if a fountain solution is provided. Furthermore, other effects can be expected such that thermal diffusion in the laser exposed area can be prevented and sensitivity can be improved.

Here, when a method is carried out such that the under layer of the present invention contains a pigment in order to have the lightness L*1 of the unexposed area in the range of not less than 0 and not more than 20, the same as mentioned before.

[Formation of a Photosensitive Layer]

In order to prepare a photosensitive layer on the support body, the support body or the surface of the under layer may be directly coated with a solution containing a photosensitive composition, and the solution may be dried and cured. To coat the photosensitive composition, for example, a bar coating method, a roll coater method, a blade coater method, a gravure coater method, a curtain flow coater method, a die coater method, a dip coater method, a spraying method and the like may be used. At this time, for the purpose of anti-foaming of the coating solution and for a smoothness of the coating film, various additives such as an anti-foaming agent, a leveling agent, a repelling inhibitor, a coupling agent and the like may also be used to the coating solution.

[Composition of a Coating Solution]

For composition of the coating solution to form the photosensitive layer of the present invention, the photosensitive composition is used as dissolved and dispersed in a solvent. Here, as a solvent, water, alcohols such as ethanol, isopropanol, n-butanol and the like; ketones such as acetone, methylethyl ketone and the like; ethers such as diethylene glycol diethyl ether, diisopropyl ether, dioxane, tetrahydrofurah, diethylene glycol and the like; esters such as ethyl acetate, butyl acetate and the like; aromatic hydrocarbons such as toluene, xylene and the like; aliphatic hydrocarbons such as n-hexane, decalin and the like; dimethyl formylamide, dimethyl sulfoxide, acetonitrile or a mixed solvent thereof can be used. The amount of the solvent used is preferably in the range of from 50 to 3000 weight parts and more preferably from 100 to 2000 weight parts based on 100 weight parts of the photosensitive composition. The amount within the range described above is economically preferable from the viewpoints of stable coating and a short period of time taken for completion of drying after coating.

Further, for improving characteristics such as water resistance or the like of the photosensitive layer, organic or inorganic fillers may also be used. The amount of the filler used is not particularly restricted as far as it does not influence on coating stability or printability. The amount is preferably from 0.1 to 100 weight parts and more preferably from 0.5 to 50 weight parts based on 100 weight parts of the photosensitive composition. The amount within the range described above is preferable as sufficient effect of addition and stable coating can be achieved, and scumming and bad ink-receptivity and the like do not take place.

[Overview of Properties of a Photosensitive Layer]

Next, in the lithographic printing plate of the present invention, the photosensitive layer is described in detail. The lithographic printing plate of the present invention is a plate for offset printing press using a fountain solution. Accordingly, the photosensitive layer is preferably hydrophilic and water-resistant (not solved in a fountain solution). So, preferably, the photosensitive layer of an area irradiated with a light by the exposure is partially melt, fused and/or foamed for converting from hydrophilic to oleophilic. Therefore, it is possible to dispense with treatments such as development, wiping-off or the like after the exposure.

The wavelength of a light used for the exposure of the printing plate of the present invention is preferably from 700 to 1200 nm. Of the wavelength region, any light coincident with the absorption wavelength region of the light absorbing agent may be used. As a light source used for the exposure, a light that is easily handled and has high power is appropriate. From these viewpoints, a laser, in particular a laser having an oscillation wavelength in the wavelength region of from 800 to 1100 nm is preferable. For example, a high-power semiconductor laser of 830 nm and a YAG laser of 1064 nm are preferable. An exposure machine equipped with such lasers has been already on the market as a so-called thermal plate setter.

### EFFECT OF THE INVENTION

When the lithographic printing plate of the present invention is used, it is possible to provide a processless lithographic printing plate, which is excellent in sensitivity and resolution, requires no post treatments such as development, wiping-off or the like and is excellent in printing plate inspection in the laser exposed area by changing only the surface of the laser exposed area into the oleophilicity.

### EXAMPLES

The present invention is now more specifically illustrated below with reference to Examples. The present invention is not limited to these Examples.

### (Synthesis of Hydrophilic Polymer A)

In a 1000 ml flask, 400 g of water was charged, and nitrogen was bubbled to remove the dissolved oxygen, followed by raising the temperature to 80° C. While nitrogen gas was fed into the flask, a monomer solution consisting of 75 g of acrylamide, 15 g of N-vinylformamide, 10 g of hydroxyethyl acrylate and 67 g of water and an initiator aqueous solution in which 0.5 g of potassium persulfate was dissolved in 50 g of water were independently dropwise added continuously over a period of 3 hours with maintaining the internal temperature at 80° C. After the dropwise addition was completed, polymerization was continued at 80° C. for 2 hours and then further at 90° C. for another 2 hours. Finally, 150 g of water was added to obtain an aqueous solution of a hydrophilic polymer A. The aqueous solution of the polymer had a viscosity of 600 mPa·s and a solid content of 15 weight %.

### (Adjustment of Photosensitive Composition B)

Next, 30 weight parts (solid content) of the hydrophilic polymer A (NV=15%), 50 weight parts (solid content) of urethane emulsion (NV=40%, product name: OLESTER (registered trademark) UD350, manufactured by Mitsui Chemicals, Inc.), 20 weight parts (solid content) of methyoxymethyl melamine resin (NV=80%, product name: CYMEL (registered trademark) 350, manufactured by Mitsui Cytec Ltd.) as a crosslinking agent, 13 weight parts (solid content) of cyanine dye (5 weight % aqueous solution of IR125 manufactured by ACROS), and 1 weight part of phosphate salt (NV=100%, product name: [PRISERF] A208 manufactured by Dai-Ichi Kogyo Seiyaku Co., Ltd.) as a hydrophilic additive were mixed by using a disper until the resulting mixture became uniform to obtain a solution of a photosensitive resin composition B.

### (Adjustment of a Coloring Coating Solution C-1)

10 g of 1 weight % aqueous solution of crystal violet (manufactured by Junsei Chemical Co., Ltd.) was mixed with 10 g of urethane emulsion (NV=40%, product name: OLESTER (registered trademark) UD350, manufactured by Mitsui Chemicals, Inc.) by using a disper until the resulting mixture became uniform to prepare a coloring coating solution C-1. The color of the solution became deep blueviolet.

### (Adjustment of a Coloring Coating Solution C-2)

10 g of water dispersible carbon black (NV=20%, CAB-O-JET (registered trademark) 200, manufactured by Cabot Specialty Chemicals, Inc.) was mixed with 20 g of urethane emulsion (NV=40%, product name: OLESTER (registered trademark) UD350, manufactured by Mitsui Chemicals, Inc.) by using a disper until the resulting mixture became uniform to prepare a coloring coating solution C-2. The color of the solution became black.

### (Adjustment of a Coloring Coating Solution C-3)

2 g of 1 weight % aqueous solution of crystal violet (manufactured by Junsei Chemical Co., Ltd.) and 2 g of water dispersible carbon black (NV=15%, CAB-O-JET (registered trademark) 300, manufactured by Cabot Specialty Chemicals, Inc.) were mixed with 20 g of urethane emulsion (NV=40%, product name: OLESTER (registered trademark) UD350, manufactured by Mitsui Chemicals, Inc.) by using a disper until the resulting mixture became uniform to prepare a coloring coating solution C-3. The color of the solution became black purple.

### (Adjustment of a Coloring Coating Solution C-4)

10 g of 1 weight % aqueous solution of acid violet 7 (manufactured by Aldrich Chemical Company, Inc.) was mixed with 10 g of urethane emulsion (NV=40%, product name: OLESTER (registered trademark) UD350, manufactured by Mitsui Chemicals, Inc.) by using a disper until the resulting mixture became uniform to prepare a coloring coating solution C-4. The color of the solution became red purple.

### (Adjustment of a Coloring Coating Solution C-5)

10 g of 1 weight % aqueous solution of patentgreen (manufactured by Tokyo Kasei Kogyo Co., Ltd.) was mixed with 10 g of urethane emulsion (NV=40%, product name: OLESTER (registered trademark) UD350, manufactured by Mitsui Chemicals, Inc.) by using a disper until the resulting mixture became uniform to prepare a coloring coating solution C-5. The color of the solution became darkgreen.

### (Adjustment of a Coloring Coating Solution C-6)

5 g of 5 weight % aqueous solution of indocyanine green (manufactured by ACROS) was mixed with 20 g of urethane emulsion (NV=40%, product name: OLESTER (registered trademark) UD350, manufactured by Mitsui Chemicals, Inc.) by using a disper until the resulting mixture became uniform to prepare a coloring coating solution C-6. The color of the solution became darkgreen.

### Example 1

### Coloring Example 1 of an Under Layer

An aluminum plate having a thickness of 0.28 mm was coated with the coloring coating solution C-1 using a wire bar #20 and then the solution was wind-dried. Then, the photosensitive resin composition B prepared in synthesis example 1 was uniformly coated using a wire bar #14 and then the composition was dried at 120° C. for 1 hour to form a photosensitive layer having a thickness of 2 μm. The color of a printing original plate was deep blueviolet. When the printing original plate prepared as described above was irradiated with laser so that an energy became 200 mJ/cm² on the plate surface using an 830 nm semiconductor laser exposure machine, an exposed area was changed to white.

### (Evaluation)

In the thus-image-formed plate, printing plate inspection was evaluated. Evaluation was carried out by observing exposure halftones using a 20× magnifier for determination.

∘: 2 to 98% halftone shape was clearly confirmed.
Δ: 50% halftone shape was confirmed. However, 2% and 98% halftone shapes were not confirmed.
X: 50% halftone shape could not be confirmed.

The lightness L* of the laser exposed area and unexposed area was carried out with a spectro-color-densitometer x-rite 528JP manufactured by X-Rite. The results are shown in Table 1 below.

### Example 2

### Coloring Example 2 of an Under Layer

An aluminum plate having a thickness of 0.28 mm was coated with the coloring coating solution C-2 using a wire bar #14 and then the solution was dried at 120° C. for 5 minutes. Then, the photosensitive resin composition B was coated in the same manner as in Example 1 and then the composition was dried to form a photosensitive layer having a thickness of 2 μm. The color of a printing original plate was black. When the printing original plate prepared as described above was irradiated with laser so that an energy became 200 mJ/cm² on the plate surface using an 830 nm semiconductor laser exposure machine, an exposed area was changed to white. The printing plate inspection was evaluated in the same manner as in Example 1. The results are shown in Table 1.

### Example 3

### Coloring Example 3 of an Under Layer

An aluminum plate having a thickness of 0.28 mm was coated with the coloring coating solution C-3 using a wire bar #20 and then the solution was dried at 120° C. for 5 minutes. Then, the photosensitive resin composition B was coated in the same manner as in Example 1 and then the composition was dried to form a photosensitive layer having a thickness of 2 μm. The color of a printing original plate was black purple. When the printing original plate prepared as described above was irradiated with laser so that an energy became 200 mJ/cm² on the plate surface using an 830 nm semiconductor laser exposure machine, an exposed area was changed to white. The printing plate inspection was evaluated in the same manner as in Example 1. The results are shown in Table 1.

### Example 4

### Application Example of a Coloring Support Body

A black polyester film (MELINEX (registered trademark) 427, manufactured by Teijin Dupont Films Limited) mixed with carbon black was coated with the photosensitive resin composition B in the same manner as in Example 1 and then the composition was dried to form a photosensitive layer having a thickness of 2 μm. The color of a printing original plate was black. When the printing original plate prepared as described above was irradiated with laser so that an energy became 200 mJ/cm² on the plate surface using an 830 nm semiconductor laser exposure machine, an exposed area was changed to white. The printing plate inspection was evaluated in the same manner as in Example 1. The results are shown in Table 1.

### Example 5

### Coloring Example of a Back Side of a Transparent Film

The back side of a transparent polyester film having a thickness of 0.19 mm (TETORON (registered trademark) HLW, manufactured by Teijin Dupont Films Limited) was coated with the coloring coating solution C-2 using a wire bar #14 and the solution was dried at 120° C. for 5 minutes to prepare a support body in which the color of the back side was black. The opposite side of a coloring layer of the support body was coated with the photosensitive resin composition B in the same manner as in Example 1 and the solution was dried to form a photosensitive layer having a thickness of 2 μm. The color of a printing original plate was black. When the printing original plate prepared as described above was irradiated with laser so that an energy became 200 mJ/cm² on the plate surface using an 830 nm semiconductor laser exposure machine, an exposed area was changed to white. The printing plate inspection was evaluated in the same manner as in Example 1. The results are shown in Table 1.

### Comparative Example 1

An aluminum plate having a thickness of 0.28 mm was coated with an urethane emulsion (NV=40%, product name: OLESTER (registered trademark) UD350, manufactured by Mitsui Chemicals, Inc.) as an under layer using a wire bar #20 and then the solution was dried at 120° C. for 5 minutes. Then, the photosensitive resin composition B was coated in the same manner as in Example 1 and then the composition was dried to form a photosensitive layer having a thickness of 2 μm. The color of a printing original plate was pale green. When the printing original plate prepared as described above was irradiated with laser so that an energy became 200 mJ/cm² on the plate surface using an 830 nm semiconductor laser exposure machine, an exposed area was changed to white. The printing plate inspection was evaluated in the same manner as in Example 1. The results are shown in Table 1.

### Comparative Example 2

An aluminum plate having a thickness of 0.28 mm was coated with the coloring coating solution C-4 using a wire bar #20 and then the solution was dried at 120° C. for 5 minutes. Then, the photosensitive resin composition B was coated in the same manner as in Example 1 and then the composition was dried to form a photosensitive layer having a thickness of 2 μm. The color of a printing original plate was red purple. When the printing original plate prepared as described above was irradiated with laser so that an energy became 200 mJ/cm² on the plate surface using an 830 nm semiconductor laser exposure machine, an exposed area was changed to white. The printing plate inspection was evaluated in the same manner as in Example 1. The results are shown in Table 1.

### Comparative Example 3

An aluminum plate having a thickness of 0.28 mm was coated with the coloring coating solution C-5 using a wire bar #20 and then the solution was dried at 120° C. for 5 minutes. Then, the photosensitive resin composition B was coated in the same manner as in Example 1 and then the composition was dried to form a photosensitive layer having a thickness of 2 μm. The color of a printing original plate was green. When the printing original plate prepared as described above was irradiated with laser so that an energy became 200 mJ/cm² on the plate surface using an 830 nm semiconductor laser exposure machine, an exposed area was changed to white. The printing plate inspection was evaluated in the same manner as in Example 1. The results are shown in Table 1.

### Comparative Example 4

An aluminum plate having a thickness of 0.28 mm was coated with the coloring coating solution C-6 using a wire bar #14 and then the solution was dried at 120° C. for 5 minutes. Then, the photosensitive resin composition B was coated in the same manner as in Example 1 and then the composition was dried to form a photosensitive layer having a thickness of 2 μm. The color of a printing original plate was darkgreen. When the printing original plate prepared as described above was irradiated with laser so that an energy became 200 mJ/cm² on the plate surface using an 830 nm semiconductor laser exposure machine, an exposed area was changed to white. The printing plate inspection was evaluated in the same manner as in Example 1. The results are shown in Table 1.

### Comparative Example 5

A white polyester film having a thickness of 0.19 mm (TETORON (registered trademark) U2, manufactured by Teijin Dupont Films Limited) was coated with the photosensitive resin composition B in the same manner as in Example 1 and then the solution was dried to form a photosensitive layer having a thickness of 2 μm. The color of a printing original plate was pale green. When the printing original plate prepared as described above was irradiated with laser so that an energy became 200 mJ/cm² on the plate surface using an 830 nm semiconductor laser exposure machine, an exposed area was changed to white. The printing plate inspection was evaluated in the same manner as in Example 1. The results are shown in Table 1.

### Comparative Example 6

The back side of a transparent polyester film having a thickness of 0.19 mm (TETORON (registered trademark) HLW, manufactured by Teijin Dupont Films Limited) was coated with the coloring coating solution C-6 using a wire bar #14 and then the solution was dried at 120° C. for 5 minutes to prepare a support body in which the color of the back side was green. The opposite side of a coloring layer of the support body was coated with the photosensitive resin composition B in the same manner as in Example 1 and then the composition was dried to form a photosensitive layer having a thickness of 2 μm. The color of a printing original plate was green. When the printing original plate prepared as described above was irradiated with laser so that an energy became 200 mJ/cm² on the plate surface using an 830 nm semiconductor laser exposure machine, an exposed area was changed to white. The printing plate inspection was evaluated in the same manner as in Example 1. The results are shown in Table 1.

TABLE 1

| | Color | | lightness L* | | |
|---|---|---|---|---|---|
| | of | | | | Printing |
| | Unexposed | Pigment-added | Unexposed | Difference | Plate |
| | Area | Area | Area | (L* 2 − L * 1) | Inspection |
| Example 1 | Deep | Under layer | 3.2 | 14.3 | ◯ |
| | blueviolet | | | | |
| Example 2 | Black | Under layer | 6.6 | 14.4 | ◯ |
| Example 3 | Black purple | Under layer | 2.7 | 10.7 | ◯ |
| Example 4 | Black | Support body | 4.9 | 17.9 | ◯ |
| Example 5 | Black | Back side | 10.5 | 13.5 | ◯ |
| | | layer | | | |
| Comparative | Pale green | — | 45.4 | 3.6 | X |
| Example 1 | | | | | |
| Comparative | Red purple | Under layer | 22.0 | 5.9 | X |
| Example 2 | | | | | |
| Comparative | Green | Under layer | 29.2 | 4.1 | • |
| Example 3 | | | | | |
| Comparative | Darkgreen | Under layer | 27.7 | 9.5 | • |
| Example 4 | | | | | |
| Comparative | Pale green | Support body | 64.4 | 5.5 | • |
| Example 5 | | | | | |
| Comparative | Green | Back side | 52.3 | 4.5 | X |
| Example 6 | | layer | | | |

### INDUSTRIAL APPLICABILITY

According to the lithographic printing plate of the present invention, the color of the non-image area (laser unexposed area) is dark and the image area (laser exposed area) becomes opaque so that the contrast is high and printing inspection by naked eye is excellent.

1. A processless lithographic printing plate requiring no post treatments after exposure to laser, wherein a difference between the lightness (L*1) of a laser unexposed area and the lightness (L*2) of a laser exposed area after irradiation with laser is 10-=(L*2−L*1)<100.

2. The processless lithographic printing plate according to claim 1, wherein the lightness (L*1) of a laser unexposed area is not less than 0 and not more than 20.

3. The processless lithographic printing plate according to claim 1, wherein a photosensitive layer is formed on a support body with an under layer interposed therebetween and a pigment in order to have the lightness (L*1) of a laser unexposed area of not less than 0 and more than 20 is contained in the under layer.

4. The processless lithographic printing plate according to claim 1, wherein a photosensitive layer is formed directly on a support body or with an under layer interposed therebetween and a pigment in order to have the lightness (L*1) of a laser unexposed area of not less than 0 and not more than 20 is contained in the support body.

5. The processless lithographic printing plate according to claim 1, wherein a photosensitive layer is formed directly on a support body or with an under layer interposed therebetween, the support body is transparent, the support body has a layer on the back surface thereof in which a pigment in order to have the lightness (L*1) of a laser unexposed area of not less than 0 and not more than 20 is contained.

6. A processless lithographic printing original plate requiring no post treatments after exposure to laser, wherein a difference between the lightness (L*1) of a laser unexposed area and the lightness (L*2) of a laser exposed area after irradiation with laser is 10≦(L*2−L*1)<100.
